(19) United States
(12) Patent Application Publication
(10) Pub. No.: US 2010/0202487 A1
(43) Pub. Date: Aug. 12, 2010

(54) SEMICONDUCTOR LASER AND METHOD FOR OPERATING A SEMICONDUCTOR LASER

(75) Inventors: Bernd Sartorius, Berlin (DE); Jochen Kreissl, Altlandsberg (DE); Ute Troppenz, Berlin (DE); Carsten Bornholdt, Berlin (DE); Martin Mohrle, Berlin (DE)

Correspondence Address: FAEGRE & BENSON LLP;PATENT DOCKETING - INTELLECTUAL PROPERTY, 2200 WELLS FARGO CENTER, 90 SOUTH SEVENTH STREET, MINNEAPOLIS, MN, 55402-3901, US

(73) Assignee: Fraundhofer-Gesellschaft zur Forderung der Angewandten Forschung e.V., Munchen (DE)

(21) Appl. No.: 12/677,774

(22) PCT Filed: Sep. 2, 2008
(86) PCT No.: PCT/EP2008/007324

§ 371 Date: Apr. 15, 2010

(30) Foreign Application Priority Data
Sep. 13, 2007 (DE) 102007044848.3

(51) Int. Cl. H01S 5/125; H01S 5/323; H01S 5/12

(52) U.S. Cl. 372/50.11

(57) ABSTRACT

A semiconductor laser includes an active region designed as a DFB laser and a passive resonator section that is optically coupled to the active region. The active region has a first section with a Bragg grating and a second section with a second Bragg grating that differs from the first Bragg grating. The two Bragg gratings differ from one another such that one and only one main mode of a DFB mode spectrum of the first section overlaps with one of two main modes of a DFB mode spectrum of the second section.

### CROSS-REFERENCE TO RELATED APPLICATION

The present application is a national phase application of PCT application PCT/EP2008/007324 filed pursuant to 35 U.S.C. §371, which claims priority to DE 10 2007 044 848.3 filed Sep. 13, 2007. Both applications are incorporated by reference in their entirety.

### TECHNICAL FIELD

The invention relates to a semiconductor laser as well as to a method for operating a semiconductor laser.

### BACKGROUND

Semiconductor lasers having an active region designed a DFB laser (distributed feed-back laser) and a passive resonator section that is optically coupled to the active region have been developed in order to permit a particularly rapid modulation of laser radiation. Thereby, one can make use of the fact that light which is reflected in the passive resonator section and is coupled into the DFB laser again, acts in a more or less intensifying or weakening manner depending on the phase position or the intensity, and thus may increase or reduce the threshold gain of the semiconductor laser, said threshold gain to be exceeded for the application of the laser activity. By way of this, a modulation of the semiconductor laser is possible by way of a manipulation of the mentioned phase position, which permits a switching on and off of the laser with comparatively low changes of a charge carrier density in the active region.

A corresponding DFB laser is described in the document US 2004/0114656 A1, whose active region, as also with the laser from the document EP 0 903 820 A2, includes two sections with two different Bragg gratings.

However, it has been found to be extremely difficult to manufacture semiconductor lasers that are suitable for desired high modulation frequencies of a magnitude of 40 GHz, according to the state of the art. Specifically, it has been ascertained that a normal semiconductor laser of the described constructional type, with a modulation by way of the manipulation of phase position of coupled-back light, tends to jump between different DFB modes, which thwarts the desired high-frequency modulation.

### SUMMARY

In some embodiments, the invention pertains to a suitable semiconductor laser that overcomes the outlined problems and thus is suitable for a very high-frequency modulation of the laser radiation. In some embodiments, this semiconductor laser may be manufactured in an as uncomplicated as possible manner and thus is also suitable for large-scale manufacture. Such a laser may be operated in accordance with a method that permits operation of the semiconductor laser with a very high modulation frequency.

In some embodiments, the jumping of modes between different DFB modes which would thwart a rapid modulation of the described type (Q-modulation) is prevented. An includes a first section with a first Bragg grating and a a second section with a second Bragg grating that is different to the first Bragg grating. The two Bragg gratings differ from one another such that in operation of the semiconductor laser, one and only one of two main modes of a DFB mode spectrum of the first section overlaps with one of two main modes of a DFB mode spectrum of the second section.

A normal DFB laser does not emit exactly at a Bragg wavelength resulting from the product of the grating period and refractive index, but there exhibit rather a so-called stop-band of a width of typically about 2 nm to 5 nm, in which a propagation of light waves is not possible, since beamed-in waves are greatly reflected here. The width of the stop-band grows with the coupling coefficients of the grating, which in turn increases with the etching depth of the grating grooves. Instead of a maximum at the Bragg wavelengths, a DFB laser thus rather displays two main modes which lie at a short-waved edge of the stop-band and a long-waved edge of the stop-band. The previously described mode jumping occurs in particular between these two main modes with common DFB lasers. However, it is this mode jumping that is prevented by way of the present invention, by virtue of the two mentioned sections of the DFB laser being off-tuned with regard to one another such that a constructive overlapping of the DFB mode spectra is only present in each case at one of the two main modes of each section.

Accordingly, an embodiment pertains to a method for operating a semiconductor laser by activating the laser with currents or current strengths, at which a laser threshold is only exceeded for a DFB mode system including the first section and the second section, but not for modes in the individual sections alone. This may be easily achieved by way of an adequately short design of the individual sections. The laser threshold is then only exceeded for the main mode, which has the same wavelength for both sections, while an undesired jumping to the respective other main mode is rendered impossible.

Of course, in some embodiments, the active region of the described semiconductor laser may include additional further sections of a suitable design, thus with Bragg gratings which are different in the described manner.

In some embodiments, the second Bragg grating has a grating period differing from the first Bragg grating in order to achieve the desired relative off-tuning of the sections of the active region. It is also possible for the laser direction to have an angle to the grating groove normal in one of the sections. Then, under certain circumstances, an effective grating period differing from the other Bragg grating may also be achieved, even with the same distance of the individual grating grooves.

Alternatively or additionally, in some embodiments, the second Bragg grating may also have a coupling coefficient differing from the first Bragg grating, e.g. by way of differing etching depth and/or being integrated into a structure with a refractive index differing from the first Bragg grating. Differently wide stop-bands of the DFB mode spectra may be formed by way of the different coupling coefficients, and additionally a suitable off-tuning of the Bragg gratings may be achieved.

The two sections of the active region may be off-tuned with respect to one another in a different manner by way of a suitable design of the Bragg gratings, in order to achieve the desired effect. Thus the Bragg gratings may e.g. be designed such that a shorter-waved one of the two main modes of the first section overlaps with a longer-waved of the two main modes of the second section. Thereby, it is of no significance as to whether the first section lies facing or distant to the passive resonator section. The stop-bands defining the distance between the two main modes of each DFB mode spectrum may have the same width in this case. Then, the desired overlapping is achieved by way of a relative off-tune of the two Bragg gratings by a stop-band width.

In other embodiments,a shorter-waved of the two main modes of the first section over-laps with a shorter-waved of the two main modes of the second section, or a longer-waved of the two main modes of the first section overlaps with a longer-waved of the two main modes of the second section. For this, the Bragg gratings may be designed such that the corresponding DFB mode spectra have a different stop-band width, which may be achieved by way of greatly different coupling coefficients caused for example by way of different etching depths of the Bragg gratings. On the other hand, only a very small relative off-tuning of the two sections may be appropriate in this case.

A transition with a λ/4 phase jump may be provided between the first Bragg grating and the second Bragg grating, in order to achieve an optical coupling between the sections of the active region which is optimal for the desired effect.

In one embodiment, the active region for the first section and the second section has a common electrical contact for applying a pump current or activation current. This leads to an advantageously simple activation of the laser, which requires no separate control of the different sections of the active region. The decisive condition of an overlapping of precisely one of two main modes of a section, with a corresponding main mode of the other section, is thereby achieved by way of the suitable technological setting of the grating parameters. A completely exact setting thereby is not necessary since the DFB modes have a certain width and thus may form a common laser mode in a certain tolerance range. Alternatively however, one may provide a separate activation of the different sections of the active region, in order thus to be able to compensate deviations from the optimal mode correlation by way of an adapted, somewhat differently weighted electronic activation of the sections.

In some embodiments, the passive resonator section of the semiconductor, such as on a side distant to the active region, includes a reflector which may be realized by way of a mirroring or by way of a passive Bragg grating or by way of a DBR (distributed Bragg reflector) or by way of a further DFB grating which is set to transparency. If the reflector is a further DFB grating set to transparency, a reflectivity of the reflector may also be modulated.

In some embodiments, the passive resonator section may include a separate electrical contact for setting a refractive index of the passive resonator section. With this, the relative phase position in the passive resonator section, of radiation which is reflected and then coupled back into the DFB laser, may be set. The refractive index may be influenced by current injection or applied electrical voltage. Alternatively or additionally, a separately contacted active section may be useful for setting the amplitude of back-coupled radiation being integrated within the passive resonator section. Instead of a PFL (passive feedback laser) which provides for simplicity of operation, one then obtains an AFL (active feedback laser) which is distinguished by way of more comprehensive activation possibilities.

In some embodiments, a particularly simple construction of a semiconductor laser of the type suggested here may be realized if the DFB laser with the two sections and the passive resonator section is constructed on a common semiconductor substrate. The semiconductor laser, may for example, be realized on the basis of a III-V connection semiconductor, such as InP or GaAs semiconductor. These materials are characterized by optical properties that are suitable for a semiconductor laser, as well as by a good contactability.

In some embodiments, in order to obtain as simple as possible construction of the semiconductor laser, the active region may include a common active layer for the first section and the second section. The Bragg gratings may be etched into this layer or, in some embodiments, into a further layer such as a waveguide layer. Thereby, they may be designed with a different grating period and/or etching depth and/or—in particular with a grating production by way of electron beam exposure—with the omission of a few grating grooves in one of the Bragg gratings, for changing an effective coupling coefficient.

In some embodiments, operation of a semiconductor laser of the presented type envisages a setting of the semiconductor laser, with which the wavelength shift entailed by an increase in the pump current, leads to a more constructive phase correlation of the wave reflected in the passive resonator section, with a laser wave, and thus the laser threshold is reduced. This is achieved if a possible laser activity of the laser section is firstly suppressed by way of a reflection of the passive resonator with an unfavorable phase position, i.e. with an as strong as possible destructive interference. This operating point may be set via the optical length of the phase section, and this length may be variably set in the finished component via the envisaged electrical activation of the refractive index. If the laser is pumped higher proceeding from this operating point, then with a higher charge carrier density, it is not only the gain that is increased, but also the refractive index and the DFB mode wavelength change, and thus move away from the operating point of the large negative interference. The reflected light wave now constructively contributes to the DFB laser mode, the laser threshold for this condition is thus smaller and the laser responds significantly more quickly than with a conventional DFB laser, which is switched on by way of increasing the charge carrier density. Vice versa, the same applies to a rapid switching-off of the semiconductor laser by way of a reduction of the pump current or of the activation current strength and thus of the charge carrier density. In some embodiments, the radiation of the semiconductor laser may be able to be modulated without any problem with modulation frequencies of greater than 30 GHz. In some embodiments, the laser may be able to be modulated at a modulation frequency of at least 40 GHz and specifically in a direct manner by way of a suitable modulation of an activation current.

### BRIEF DESCRIPTION OF THE FIGURES

Embodiment examples of the invention are described hereinafter by way of the FIGS. 1 to 7.

FIG. 1 is a cross section through a semiconductor laser according to an embodiment of the invention.

FIG. 2 is a diagram with DFB mode spectra of two sections of a DFB laser, of the semiconductor laser of FIG. 1.

FIG. 3 is a diagram of the DFB mode spectra of a semiconductor laser in accordance with another embodiment of the invention.

FIG. 4 is a diagram of the DFB mode spectra of a semiconductor laser in accordance with another embodiment of the invention.

FIG. 5 is a schematic representation of a semiconductor laser in accordance with another embodiment of the invention.

FIG. 6 is a schematic representation of a semiconductor laser in accordance with another embodiment of the invention.

FIG. 7 is a diagram that illustrates a dependency of a threshold gain of the described semiconductor laser, on a phase position of a wave reflected in the passive resonator section.

### DETAILED DESCRIPTION

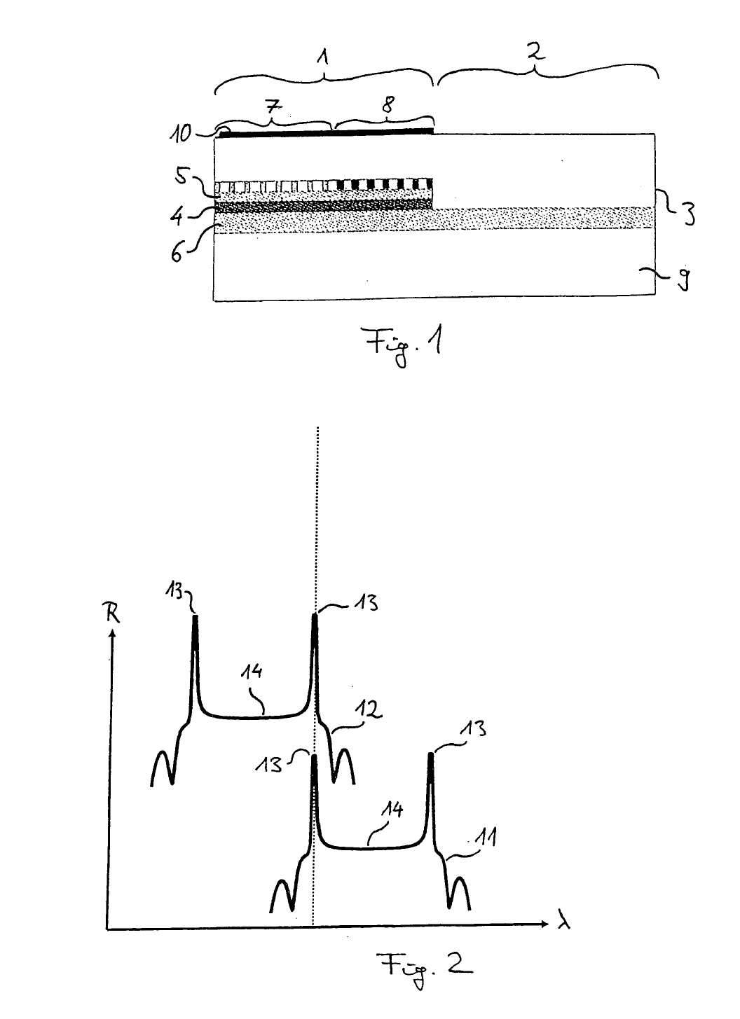

A semiconductor laser is illustrated in FIG. 1, including an active region designed as a DFB laser as well as a passive resonator section 2 that is optically coupled to the active region 1. The resonator section 2 at a side distant to the active region 1 includes a reflector 3 which in the illustrated embodiment is realized as a mirroring of a facet of the semiconductor laser. Laser radiation which is produced in the region 1, is reflected by this reflector and after passing the resonator section 2 is coupled into the DFB laser formed by the active region 1. Thus produced laser radiation is finally coupled out at a surface of the semiconductor laser, said surface lying opposite the reflector 3.

In the active region 1, the semiconductor laser has an active layer 4 as well as a structured laser waveguide layer 5 lying thereabove, and a further laser waveguide layer 6 which lies therebelow and which extends over the passive resonator section 2.

The active region 1 of the semiconductor laser has a first section 7 in which the structured laser waveguide layer 5 includes a first Bragg grating and a second section 8 with a second Bragg grating which is different from the first Bragg grating and which is likewise structured into the structured laser waveguide layer 5. Thereby, the two Bragg gratings differ from one another such that with an operation of the semiconductor laser, one and only one of two main modes of a DFB mode spectrum of the first section 7 overlaps with one of two main modes of a DFB mode spectrum of the second section 8, as is described in yet more detail further below.

Modifications to the semiconductor laser shown in FIG. 1 may also include further sections of the active region 1 which—as the sections 7 and 8 here—are provided with different Bragg gratings. The active layer 4 spans the first section 7 as well as the second section 8 and serves as an active medium for both sections 7 and 8. The whole semiconductor laser, with the two sections 7 and 8 of the DFB laser and with the passive resonator section 2, are built on a common semiconductor substrate 9. In some embodiments, the common semiconductor substrate 9 may be formed of InP or GaAs.

Finally, and as seen in FIG. 1, a common electrical contact 10 that is arranged on a surface of the semiconductor laser may,may accommodate a pump current or activation current, with which both sections 7 and 8 of the active region 1 are activated.

In the illustrated embodiment of FIG. 1, the active layer 4 includes a multi-quantum well structure with four InGaAsP wells having a thickness of 7 nm embedded in 10 nm thick layer of InGaAsP (band edge 1300 nm) barriers. The active layer is encased by the structured laser waveguide layer 5 as an upper waveguide layer 6 of InGaAsP with a band edge of 1150 nm and a thickness of 150 nm, and the further laser waveguide layer 6 is a waveguide layer of InGaAsP with a band edge of 130 nm and a thickness of 250 nm Gratings with a coupling coefficient of 130/cm are etched into the upper waveguide layer, which leads to a stop-band width of approx. 5 nm The gratings have been directly written by an electron beam exposure device and have been transferred into the semiconductor with a dry etching process. The Bragg wavelength of the one grating lies at 1550 nm, and that of the other grating is shifted by 5 nm into the long-waved region. The two DFB sections 7 and 8 are in each case 130 μm long, a length at which, according to experience values, a laser activity may not be achieved with these structures. Unexpectedly, a laser activity is reliably achieved with these structures with a length of 260 μm.

In some embodiments, the active layer 4 and the upper waveguide layer have been etched away in the passive section of a length of 300 μm, given by the passive resonator section 2. The leading of the wave is achieved by the continuous lower waveguide layer. The laser axis and the wave-leading in this is effected by way of the formation of a ridge waveguide laser structure. The DFB facet is coated in an antireflex manner and the facet at the passive section is provided with a mirroring with reflectivities of more than 90%. The two DFB sections 7 and 8 are provided with a common electrical and high-frequency-capable contact. A further separate electrical contact at the passive section or phase section permits the refractive index control and thus the setting of the phase position of the reflected signal relative to the phase of the waveguide of the DFB laser.

With the embodiment illustrated in FIG. 1, the second Bragg grating, which is arranged in the second section 8 of the active region 1, has a slightly smaller grating period than the Bragg grating in the first section 7. For this purpose, the second Bragg grating includes etched-in grating grooves with a slightly smaller distance than the first Bragg grating. Alternatively, the first Bragg grating could also be provided with a larger effective grating period, by way of the laser direction in one of the sections 7 or 8 having a non-negligent angle to the grating groove normal, given indeed the same distance of the grating grooves forming the Bragg gratings.

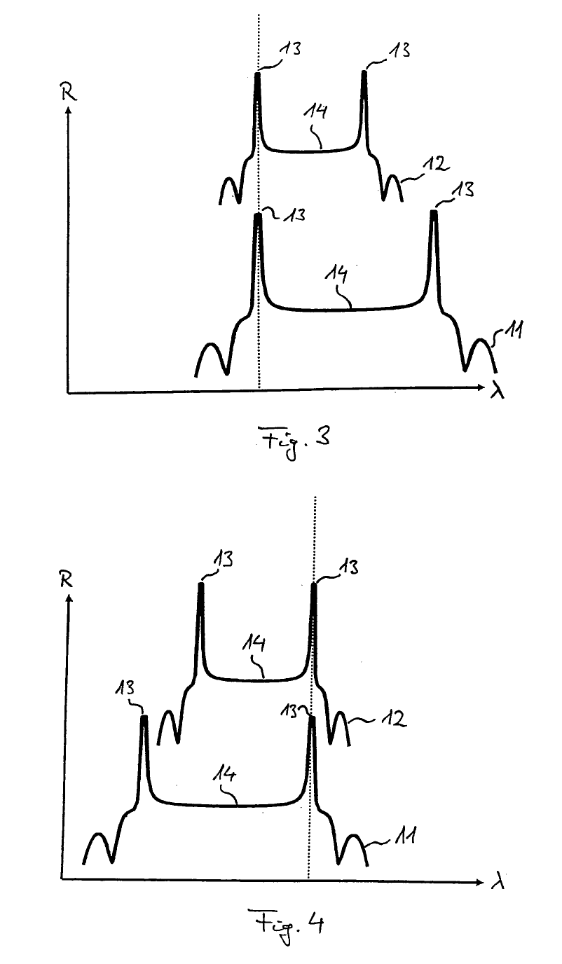

FIG. 2 shows a diagram, in which the relative reflectivities R are represented in dependence on a wavelength λ for the two sections 7 and 8 of the active region 1, which is plotted on the abscissa, said reflectivities in each case representing a DFB mode spectrum 11 and 12 of the respective section 7 or 8, respectively, of the DFB laser. Thereby, a DFB mode spectrum 11 that is shifted to higher wavelengths is assigned to the first section 7, and a DFB mode spectrum 12 that is shifted to lower wavelengths is assigned to the second section 8. Main modes 13 of the two DFB mode spectra 11 and 12 which in each case are separated by a stop-band 14, may be recognized and these main modes are typical for DFB lasers.

FIG. 2 now shows that on account of a suitable selection of the grating periods of the two Bragg gratings, a shorter-waved of the two main modes 12 of the first section 7 is congruent to or aligns with a longer-waved of the two main modes 13 of the second section 8. The stop bands thereby in the present case have the same width of about 5 nm, wherein the two DFB mode spectra 11 and 12 are displaced to one another by this width with an otherwise similar shape.

FIG. 3 shows a corresponding diagram for another embodiment in which, because of a slightly different design of the two Bragg gratings, a shorter-waved of the two main modes 13 of the first section 7 overlaps with a shorter-waved of the two main modes 13 of the second section 8, while the longer-waved main modes 13 fall apart, since the stop-bands 14 here have a different width, wherein additionally the DFB mode spectrum 12 of the second section 8 is displaced to shorter wavelengths by half the difference of the widths of the stop-bands 14. The different width of the stop bands 14 thereby results due to different coupling coefficients of the two Bragg gratings, wherein the Bragg grating of the first section 7 here has a greater degree of modulation on account of the greater etching depth. With this, different coupling coefficients result in the two sections 7 and 8, by way of which the different shapes of the two DFB mode spectra 11 and 12 result. Here too, only one of the two main modes 13 of the DFB mode spectrum 11 of the first section 7 overlaps with one of the second main modes 13 of the DFB mode spectrum 12 of the second section 8.

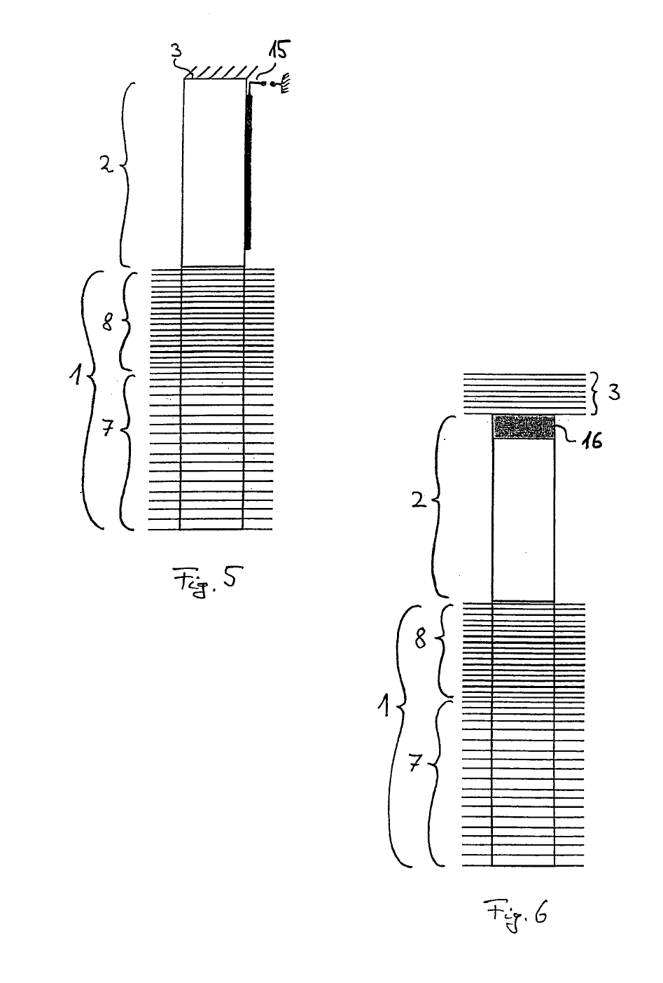

Another embodiment is shown in FIG. 4, which again only differs from the previously described examples by way of a slightly different design of the two Bragg gratings. Here, a longer-waved of the two main modes 13 of the first section 7 overlaps with a longer-waved of the two main modes 13 of the second section 8, while the shorter-waved main modes 13 fall apart on account of the different width of the stop-bands 14. This is again achieved by way of a difference in the coupling coefficients in the two sections 7 and 8, resulting from different etching depths of the structured laser waveguide layer 5 in the two sections 7 and 8, wherein here the Bragg wavelength of the Bragg grating in the first section 7 is shorter by about half the difference of the widths of the stop-bands 14.

In the embodiments described thus far, a difference in the Bragg wavelengths of the two sections 7 and 8 may not only be achieved by way of different grating periods of the two Bragg gratings, but also by way of the structured laser waveguide layer 5 and/or the other laser waveguide layer 6 in the region of the second section 8 having a different refractive index than in the region of the first section 7. Even with the same distance of the grating grooves in the two sections 7 and 8, the desired difference between the Bragg gratings may result by way of a wave propagation speed which is different in the two sections 7 and 8. In particular with the embodiment illustrated by way of FIGS. 3 and 4, a different modulation degree of the Bragg gratings in the sections 7 and 8 may also result by way of omitting a few grating grooves for changing an effective coupling coefficient, given a grating production by electron beam exposure in one of the two sections 8 and 7.

In some embodiments, one further envisages a λ/4 phase jump being provided at a transition between the two sections 7 and 8, between the two Bragg gratings which meet there.

A further semiconductor laser is shown in FIG. 5 in a stylized manner, which differs from the semiconductor laser shown in FIG. 1 only by way of the fact that the passive resonator section 2 includes a separate electrical contact 1, by way of which the refractive index and the optical length of the completed manufactured phase section, thus of the passive resonator section 2, may be electrically set to required value in a variable manner—by way of current injection or applying a voltage.

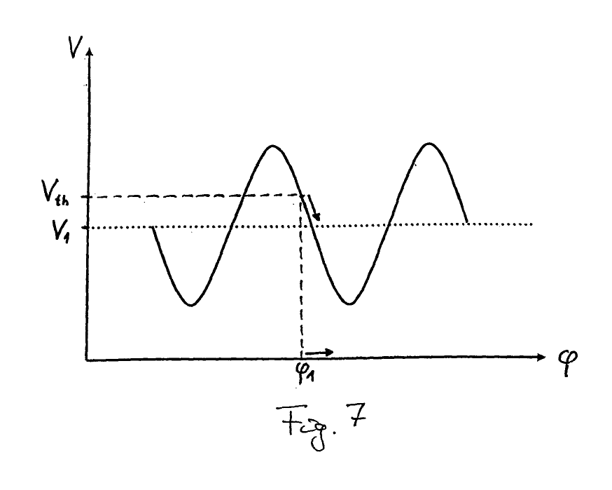

Another embodiment is shown in FIG. 6. The semiconductor laser of FIG. 6 differs from the semiconductor laser of FIG. 1 only in the region of the reflector 3, wherein recurring features are again provided with the same reference numerals. In this embodiment, the reflector 3 is a passive Bragg grating, but instead of this however, one may also provide a weakly pumped further DFB grating which is sent to transparency. Moreover, a separately contacted active section 16 for setting an amplitude (gain or damping) of back-coupled radiation, is more-over integrated in the direct vicinity of the reflector 3 within the otherwise passive resonator section 2. The semiconductor laser shown in FIG. 6 is an AFL-laser in contrast to the previously described PFL lasers. This semiconductor laser permits a control of the intensity of back-coupled radiation and by way of this, a modulation of laser radiation emitted by the semiconductor laser. If the passive Bragg grating which forms the reflector 3, is replaced by a further weakly pumped DFB grating, then a suitable modulation may also be effected by way of an activation of this DFB grating.

In some embodiments, the semiconductors laser described by way of FIGS. 1 to 6, as directed, are operated with activation current strengths, with which the individual sections 7 and 8 alone do not exceed their respective laser threshold, since the volume of the active layer 4 in these sections 7 and 8 is too small for a switching-on of the DFB laser, which is limited to these lower regions. Since the DFB laser contained in the semiconductor laser from the active region 1, thus with the applied activation currents, may only be switched on as a whole, the semiconductor laser is triggered only exactly in the main mode 13, which lies in the two sections 7 and 8 at the same wavelength.

The threshold gain or charge carrier density required for triggering this selected main mode 13 is however again dependent on the phase position of the laser radiation which is reflected by the reflector 3 and coupled back into the active region 1. The dependence of this threshold gain on the phase position of the laser radiation which is coupled back into the active region 1 after reflection at the reflector 3, is illustrated schematically in the diagram shown in FIG. 7. The phase position φ is thereby plotted on the abscissa, the threshold gain V on the ordinate.

The semiconductors laser described by way of FIGS. 1 and 6 are now set by way of a suitable choice of the geometry and, as the case may be, of the refractive index of the passive resonator region 2, such that the phase position, given a pump current strength which leads to an gain V₁ lying slightly below the corresponding threshold gain Vₜₕ, assumes a value indicated in FIG. 7 at φ₁, with which an enlargement of the value of the phase position φ results in a reduction of the threshold gain, wherein moreover an oscillation build-up of the semiconductor being effected with a subsequent increase in the pump current, effects an increase of the phase position φ on account of a refractive index change. This setting has the result that a slight increase of the pump current lets the semiconductor laser build up oscillation, and the threshold gain recede, which leads to an extraordinarily rapid oscillation build-up procedure. The development of the current phase position φ and the corresponding threshold gain V with such an oscillation build-up procedure is illustrated in FIG. 7 by two arrows. In the same manner, a subsequent slight reduction of the pump current below the current threshold current, which corresponds to the current threshold gain, leads to a rapid end of the radiation production, since simultaneously the current phase position φ moves back to the value indicated at φ₁ which is why the current threshold gain increases again. The described semiconductor lasers may therefore be directly modulated in a very simple manner by way of a suitable high-frequency, time-dependent pump current of the DFB laser, wherein in particular for example, laser radiation pulsed for a signal transport may be produced with modulation frequencies of more than 40 GHz. Such a mode jumping between different modes of the DFB mode spectrum, which thwarts high-frequency laser signals, is thereby prevented by way of the described design of the two Bragg gratings and the resulting characteristics of the DFB mode spectra 11 and 12 of the two sections 7 and 8 of the active region 1.

However, significantly more restricted physical limits are placed on the modulation frequency of a normal DFB laser. The most important parameter thereby is the differential gain which may be described with the gain g and the charge carrier density n, as dg/dn. The charge carrier density n in the active material is lifted above the threshold density nₜₕ by way of current injection into the DFB laser. The more the gain effected by this exceeds a threshold gain, the quicker does the DFB laser switch on and thus the more high-frequency it is to modulate. The so-called quantum well structures, which may also be provided with the semiconductor lasers described here, thereby entail advantages compared to solid layers.

Even with quantum wells, it was not possible until now to realize modulatable lasers for a data rate of 40 Gb/s in a reliable manner. With PFL lasers of the known type, such a high-frequency modulation is theoretically possible if the mode jumping described further above is prevented. The functioning principle of such a PFL laser is based on driving up the laser threshold of the desired DFB mode by way of a destructively set phase position, and then by way of modulation of the active region with the DFB laser, of increasing the charge carrier density and thus the gain, as well lowering the laser threshold by way of a phase position of the reflected wave being shifted towards a constructive phase position. Until now, it was only possible by way of the selection of selected PFL lasers to obtain semiconductor lasers which with such a setting do not jump to another mode, which with a corresponding setting has a lower threshold. Only in exceptional cases, with a conventional PFL laser, is the destructive back-coupling for both main modes of a DFB mode spectrum simultaneously achieved, said backcoupling being necessary for a setting of the described type. The cause for this is the dispersion of the passive resonator section which is also to be indicated as phase section. Although components with the necessary phase correlation may also be found by way of selection, specifically also from conventional PFL lasers, another solution to the problem must be found for a reproducible manufacture of high-frequency modulatable PFL lasers with a good yield and for an optimization of the functionality of such lasers. The solution of this problem by way of achieving a robust single modality of PFL lasers forms the core of the present described invention.

1. A semiconductor laser comprising;
an active region designed as a DFB laser, the active region including a first section with a first Bragg grating and a second section with a second Bragg grating different than the first Bragg grating; and
a passive resonator section that is optically coupled to the active region,
wherein the two Bragg gratings differ from one another such that one and only one of two main modes of a DFB mode spectrum of the first section overlaps with one of two main modes of a DFB mode spectrum of the second section.

2. A semiconductor laser according to claim 1, wherein the second Bragg grating has a grating period which differs from the first Bragg grating and/or a coupling coefficient which differs from the first Bragg grating and/or is integrated into a structure with a refractive index differing from the first Bragg grating.

3. A semiconductor laser according to claim 1, wherein a laser direction in one of the sections has a non-negligent angle to the grating groove normal.

4. A semiconductor laser according to claim 1, wherein a shorter-waved of the two main modes of the first section overlaps with a longer-waved of the two main modes of the second section.

5. A semiconductor laser according to claim 1, wherein a shorter-waved of the two main modes of the first section overlaps with a shorter-waved of the two main modes of the second section.

6. A semiconductor laser according to claim 1, wherein a longer-waved of the two main modes of the first section overlaps with a longer-waved of the two main modes of the second section.

7. A semiconductor laser according to claim 1, wherein a transition with a λ/4 phase jump is provided between the first Bragg grating and the second Bragg grating.

8. A semiconductor laser according to claim 1, wherein the first section and the second section of the active region have common electrical contacts.

9. A semiconductor laser according to claim 1, wherein the passive resonator section at a side distant to the active region comprises a reflector selected from the group consisting of a mirroring, a passive Bragg filter, or a weakly pumped further DFB grating.

10. A semiconductor laser according to claim 1, wherein the passive resonator section comprises a separate electrical contact for setting a refractive index of the passive resonator section.

11. A semiconductor laser according to claim 1, wherein a separately contacted active section for setting an amplitude of back-coupled radiation is integrated within the passive resonator section.

12. A semiconductor laser according to claim 1, comprising a InP substrate or GaAs substrate.

13. A method for operating a semiconductor laser having an active region designed as a DFB laser, the active region including a first section with a first Bragg grating and a second section with a second Bragg grating different than the first Bragg grating, and a passive resonator section that is optically coupled to the active region, the two Bragg gratings differing from one another such that one and only one of two main modes of a DFB mode spectrum of the first section overlaps with one of two main modes of a DFB mode spectrum of the second section, the method comprising:
activating the laser with current strengths, with which a laser threshold is only exceeded for a system including the first section and the second section.

14. A method according to claim 13, wherein on account of a suitable dimensioning and/or setting of the semiconductor laser, a wavelength shift entailed by an increase of the pump current, leads to a more constructive phase correlation of the wave reflected in the passive resonator section, with the laser wave, and thus the laser threshold is reduced.

15. A method according to claim 13, wherein a laser radiation of the semiconductor laser is modulated in a direct manner by way of a time-dependent activating current of the DFB laser with a frequency of at least 30 GHz or a data signal of at least 30 Gb/s.
